(19) United States
(12) Patent Application Publication
(10) Pub. No.: US 2015/0237756 A1
(43) Pub. Date: Aug. 20, 2015

(54) METHOD AND APPARATUS FOR SEAMLESSLY AFFIXING A PROTECTIVE FILM TO AN ELECTRONIC DEVICE

(71) Applicant: Google Technology Holdings LLC, Mountain View, CA (US)

(72) Inventors: David K. Lim, Green Oaks, IL (US); Michael J. Formenti, Channahon, IL (US); Jason P. Wojack, Libertyville, IL (US)

(73) Assignee: MOTOROLA MOBILITY LLC, Chicago, IL (US)

(21) Appl. No.: 14/243,917

(22) Filed: Apr. 3, 2014

Related U.S. Application Data
(60) Provisional application No. 61/942,181, filed on Feb. 20, 2014.

(51) Int. Cl. H05K 5/06; B29C 45/14

(52) U.S. Cl. CPC H05K 5/064; B29C 45/14467

(57) ABSTRACT

The present disclosure provides for a method for seamlessly affixing a protective film to an electronic device. The method includes affixing the protective film to a topside of a lens such that an empty space is formed between a perimeter of the lens and the protective film. The method further includes inserting housing material within the empty space such that the protective film is seamlessly affixed to the topside of the lens and the housing material.

### RELATED APPLICATIONS

This application is a non-provisional application of co-pending and commonly assigned U.S. Provisional Patent Application No. 61/942,181, filed on Feb. 20, 2014, from which benefits under 35 USC §119(e) are hereby claimed and the contents of which are hereby incorporated by reference herein.

### FIELD OF THE DISCLOSURE

The present disclosure relates to a protective film for an electronic device and more particularly to a method and apparatus for seamlessly affixing a protective film to a lens and housing of the electronic device.

### BACKGROUND

Some lenses of electronic devices, such as tablets, mobile phones, personal media players, and the like, are prone to breaking or shattering, for instance when the electronic device is dropped or otherwise forcibly comes into contact with a hard surface. However, current mechanisms for protecting the lens of an electronic device have some shortcomings. For example, such mechanisms do nothing with respect to minimizing the undesirable feel of seams between the lens and exterior housing of the electronic device. Moreover, other mechanisms for protecting the lens of an electronic device limit the placement of decorations or ornamental designs on the lens.

### BRIEF DESCRIPTION OF THE FIGURES

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is a diagram of an electronic device that is configurable to implement embodiments of the present teaching.

FIG. 2 illustrates one example of an apparatus having a protective film, lens and housing configured in accordance with one embodiment of the present teachings.

FIG. 3 is a logical diagram illustrating a general method of seamlessly affixing a protective film to a lens and housing material of an electronic device in accordance with the present teachings.

FIG. 4 is a logical diagram illustrating a more detailed method of seamlessly affixing a protective film to a lens and housing material of an electronic device in accordance with the present teachings.

FIG. 5 is a schematic diagram illustrating a view of a molding tool seamlessly affixing a protective film to a lens and housing material of an electronic device in accordance with the present teachings.

FIG. 6 is a schematic diagram illustrating another view of the molding tool seamlessly affixing the protective film to the lens and housing material of the electronic device in accordance with the present teachings.

FIG. 7 is a schematic diagram illustrating still another view of the molding tool seamlessly affixing the protective film to the lens and housing material of the electronic device in accordance with the present teachings.

FIG. 8 is a schematic diagram illustrating yet another view of the molding tool seamlessly affixing the protective film to the lens and housing material of the electronic device in accordance with the present teachings.

FIG. 9 is a schematic diagram illustrating a top housing plate and bottom housing plate of an electronic device having a protective film seamlessly affixed to the lens and extending to cover at least a portion of the bottom housing plate in accordance with the present teachings.

FIG. 10 is a schematic diagram illustrating a top housing plate and bottom housing plate of an electronic device having a protective film seamlessly affixed to the lens and extending to cover a portion of the top housing plate in accordance with the present teachings.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention. In addition, the description and drawings do not necessarily require the order illustrated. It will be further appreciated that certain actions and/or steps may be described or depicted in a particular order of occurrence while those skilled in the art will understand that such specificity with respect to sequence is not actually required.

The apparatus and method components have been represented where appropriate by conventional symbols in the drawings, showing only those specific details that are pertinent to understanding the embodiments of the present disclosure so as not to obscure the disclosure with details that will be readily apparent to those of ordinary skill in the art having the benefit of the description herein.

### DETAILED DESCRIPTION

Generally speaking, pursuant to the various embodiments, the present disclosure provides for a method for seamlessly affixing a protective film to an electronic device. The method includes affixing a protective film to a topside of a lens such that an empty space is formed between a perimeter of the lens and the protective film. The method also includes inserting housing material within the empty space such that the protective film is seamlessly affixed to the topside of the lens and the housing material.

Further in accordance with the teachings provided herein is an apparatus configured with a seamlessly affixed protective film. The apparatus includes a lens having a topside, a bottomside, and a perimeter around the lens. The apparatus also has a housing surrounding at least a portion of the perimeter of the lens, wherein a seam separates the lens and housing. Further, the apparatus has a protective film affixed during a manufacturing process to cover the topside of the lens and to extend across the seam to cover at least a portion of the housing.

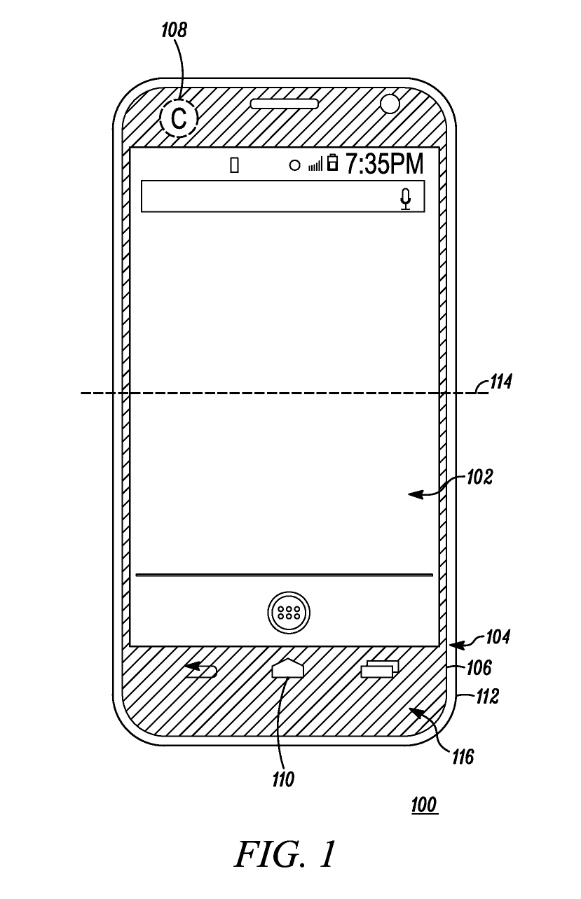

Referring now to the drawings, and in particular FIG. 1, which illustrates a plan view of a portable electronic device 100, also referred to herein as a portable device, which is configurable to implement embodiments of the present teachings. Although the electronic device 100 depicted in FIG. 1 is a smartphone, the embodiments disclosed herein are not limited to smartphones but may be implemented on any other type of electronic device having a lens surrounded at its perimeter by a housing. For example, instead of a smartphone, the electronic device 100 can be a cellular phone, a phablet, a tablet, a television, a computer monitor, a camera, a wearable device such as a smart watch or smart glasses, and the like.

As shown, the electronic device 100 has a lens 102 surrounded by a housing 104 at a perimeter or outer edge 106 of the lens 102. As shown, the lens 102 includes a viewing region (shown with no shading) where images can be displayed thereon and a non-viewing region 116 (shown with hashing), which does not display images. The housing 104 surrounds at least a portion of the lens perimeter 106 and, in an embodiment, surrounds the entire lens perimeter 106 as illustrated in FIG. 1. Moreover, a reference number 112 delineates a perimeter of a top housing plate 104. When the electronic device 100 is fully assembled, the top housing plate 104 is connected to and abuts a bottom housing plate (not shown) at the housing perimeter 112.

Accordingly, as used herein, the topside of the lens forms a portion of an external surface of an assembled electronic device and includes the area having the viewing region. Whereas, a bottomside or underside of the lens forms a portion of an internal surface of the assembled electronic device and may be adjacent to internal hardware of the electronic device. Also, where the external housing of an assembled electronic device forms two pieces or plates, as used herein, the top housing plate means the housing piece that is directly adjacent to and abuts the lens, and the other housing plate is termed herein as the bottom housing plate.

In accordance with conventional manufacturing techniques, when the housing 104 is formed around the lens 102 of the electronic device 104, the fully assembled product has a seam, which separates the lens 102 and the housing 104, at the perimeter 106. In general, a seam is caused or formed by two abutting surfaces or edges. In the above case, the seam is formed or caused by the abutting surfaces or edges of the lens 102 and the housing 104. In the prior art, this seam is perceptible by touch and, thereby, causes an undesirable aesthetic look and feel, and, hence, a diminished experience for some electronic device users. However, in embodiments described and illustrated herein, for instance by reference to FIGS. 3-10, a protective film is disposed on and affixed or attached to the lens 102 and to the housing 104 during manufacturing to cover the above-described seam between the lens 102 and the housing 104 so that this seam is no longer perceptible by touch or such perceptibility is greatly diminished.

One benefit of the present teachings is, thus, the minimization or elimination of the undesirable aesthetic look and feel of the seam between the lens 102 and the housing 104. Also, applying the protective film during manufacturing lends to the durability of the protective film. Moreover, the method for affixing the protective film to the lens and housing of the electronic device can be made more efficient by combining this method with an injection molding process, such as a glass insert molding process, for manufacturing the top housing plate of the electronic device.

Also illustrated, the electronic device 100 includes various cosmetic decorations on the non-viewing portion 116 of the lens, and, in one embodiment, the shading of the non-viewable portion 116 can indicate a further decoration applied to the lens 102. In one example, a company logo 108 is illustrated at the top of the non-viewing portion 116. In addition, function related icons 110 (three of which are shown, with only one being labeled) appear at the bottom of the non-viewing portion 116. In some examples, these icons 110 are formed in the protective film, which is disposed on the lens 102. Accordingly, another benefit of the present teachings is that decorations can still be readily applied to the lens and, in an embodiment, to the protective film affixed to the lens, for instance during the same process in which the protective film is seamlessly applied to the lens and housing.

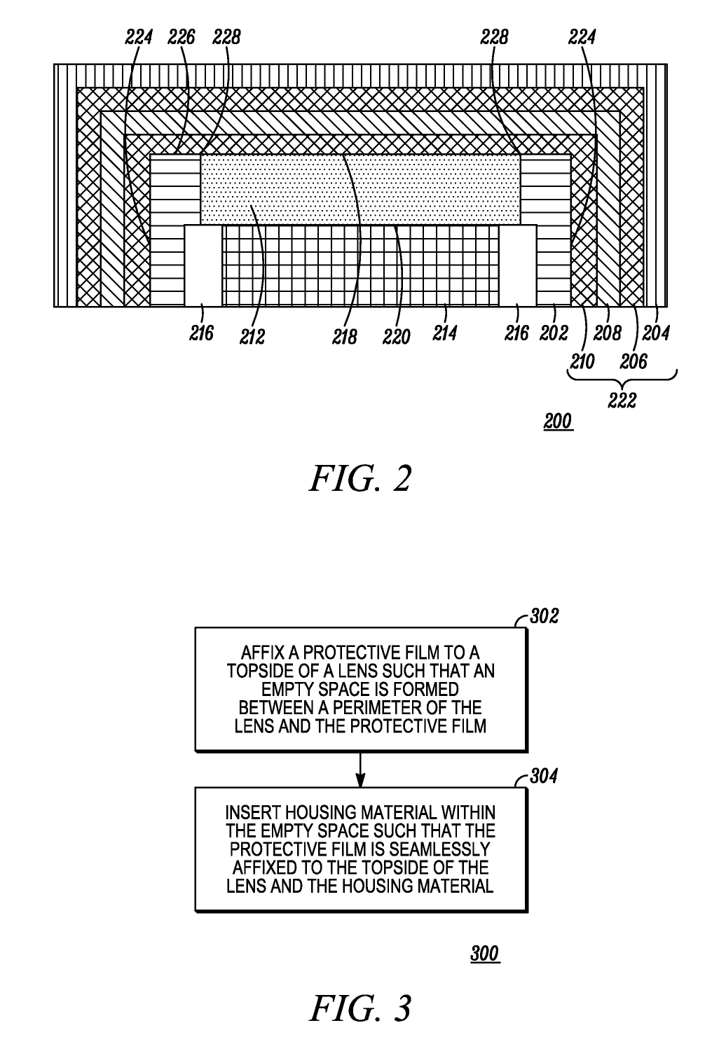

Turning now to FIG. 2, which depicts one example of an apparatus 200 configured with a seamlessly affixed protective film. The apparatus 200, accordingly, includes a protective film 222, a lens 212, a display assembly 214, and a housing 202, such as a top housing plate, for an electronic device, in accordance with one embodiment of the present teachings. For example, the view illustrated in FIG. 2 is a cutaway view of the electronic device 100 of FIG. 1 at a cross-section 114.

The lens 212 is configured and functions to provide a transparent surface on which images produced by the display assembly 214 are presented. As shown, the lens 212 has a topside 218, a bottomside 220, and a perimeter, such as the perimeter 106 illustrated in relation to the lens 102 of FIG. 1, which also delineates a seam 228 between the lens 212 and the housing 202. Different embodiments of the apparatus 200 can include different types of lenses. In one embodiment, the lens 212 is made of a material or materials such that the lens 212 does not flex or bend once included in an assembled electronic device. For example, the lens 212 is a transparent lens made of glass. In another example, the lens 212 is a transparent lens made of rigid plastic, which for instance is fashioned from one or more materials including, but not limited to, poly(methyl methacrylate) (PMMA) or polycarbonate (PC). In another embodiment, the lens 212 is a flexible lens capable of bending and flexing. Moreover, the lens 212 can have a planar or substantially planar shape such as with traditional two-dimensional lenses or can have a curvature, such as a three-dimensional shape.

The protective film 222 is configured and functions to protect the lens 212 and housing 202 in one or more ways or manners depending, for instance, at least in part on the material used to construct the film 222 and the sequence in which layers of such material are disposed on the lens 212. In one example, the protective film 222 protects the lens 212 and housing 202 from scratches, and, thereby, provides a scratch-resistant coating for the lens 212 and housing 202. In another example, the protective film 222 protects the lens 212 and housing 202 from cracking, shattering, and/or breaking; and, should breakage occur, pieces of the shattered lens 212 or housing can be maintained within the confines of the affixed film 222.

In an embodiment, the protective film 222 is formed from one or more layers of material. In particular embodiments, the protective film 222 includes one or more of the following materials alone or in any suitable combination: PMMA; PC; a diamond-like material; polyethylene terephthalate (PET); siloxane, to name a few. For example, an extrusion manufacturing process is used to form a continuous protective film 222 from a raw material. In another example, a co-extrusion process is used to form a single protective film 222 having multiple layers of different types of materials, which are bonded or fused together. The product of the co-extrusion process is, thereby, referred to herein as a co-extrusion. However, any suitable process, including one that uses one or more adhesives to bond multiple layers, can be used to create the protective film 222, which is then seamlessly affixed to the lens 212 and the housing 202 in accordance with the present teachings.

As shown in FIG. 2, the protective film 222 is a co-extrusion that includes four layers 204, 206, 208, and 210, but, in other embodiments, the protective film 222 includes fewer or more layers. The layer 210 of the protective film 222 is affixed to the topside 218 of the lens 212 and to the housing 202 during manufacturing of the electronic device, thereby covering the seam between the lens 212 and the housing 202 at the perimeter of the lens 212. For example, the protective film 222 is affixed to the topside 218 of the lens 212 and to the housing 202 using a co-molding, thermo-forming, or adhesive bonding process. This covering of the seam is referred to herein and defines a protective film being “seamlessly” applied or affixed to a topside of a lens and also to the housing 202 surrounding the perimeter of the lens. That the protective film 222 is affixed during manufacturing allows the film 222 to be more securely affixed to the lens 212 and the housing 202 than if manually applied to the lens 212 and the housing 202. In one example, the housing 202 is a top housing plate, and the protective film 222 is affixed during an injection molding manufacturing process that also molds the top housing plate to the lens 212.

The other layers 204, 206, and 208 are referred to as being “formed on” or “disposed over” an underlying layer in a stack-up arrangement. In one particular stack-up arrangement, the protective film 222 includes a diamond-like nano-composite layer 204 disposed over a first poly(methyl methacrylate) layer 206, disposed over a polycarbonate layer 208, disposed over a second PMMA layer 210, which is affixed to the topside 218 of the lens 212 and to the housing 202. Thus, in accordance with this illustrative stack-up arrangement, the protective film 222 includes a PMMA layer 210 in contact with the lens 212 and the housing 202 and further includes a PC layer 208 disposed over the PMMA layer 210 and a PMMA layer 206 disposed over the PC layer 208. A layer of the protective film being in contact with a lens and/or housing means that the layer is directly adjacent to and bonded, attached, or affixed directly to the lens or housing without an intervening layer of the protective film therebetween.

Other embodiments of the protective film 222 include a layer of material other than PMMA in contact with the lens 212 and housing 202. These additional embodiments may or may not include additional layers formed on the layer that is in contact with the lens 212 and housing 202. For example, the protective film 222 includes a polycarbonate layer in contact with the lens 212 and housing 202. The protective film 222 may also further include a poly(methyl methacrylate) layer disposed over the polycarbonate layer.

In the embodiment illustrated in FIG. 2, the protective film 222 also includes the layer 204 that is constructed from a diamond-like material, such as a diamond-like nano-composite (DLN) or diamond-like carbon (DLC), which is a material that has properties that resemble but does not duplicate diamond. The term diamond-like nano-composite means a composite material that includes DLC and at least one other material such as siloxane. The term diamond-like carbon is meant to include amorphous materials and hydrogenated amorphous materials having a mixture of sp² and sp³ hybridized carbon and hydrogen, which are characterized by properties that resemble, but do not duplicate diamond. As illustrated, the layer 204 of diamond-like material is formed on additional layers of the protective lens 222. However, in an alternative embodiment, the layer 204 of diamond-like material is applied directly to the lens 212. Including the layer 204 of diamond-like material provides an abrasion or scratch resistant coating for the lens 212.

In some other embodiments, an anti-fingerprint layer (not pictured) is further disposed over the layer 204 of diamond-like material. The anti-fingerprint layer illustratively provides a hydrophobic treatment to facilitate more easily cleaning the surface while maintaining a smooth feel to a glass lens or providing a glass-like feel to a rigid plastic lens. In one embodiment, the anti-fingerprint layer is constructed from a fluorocarbon material having a siloxane functional group.

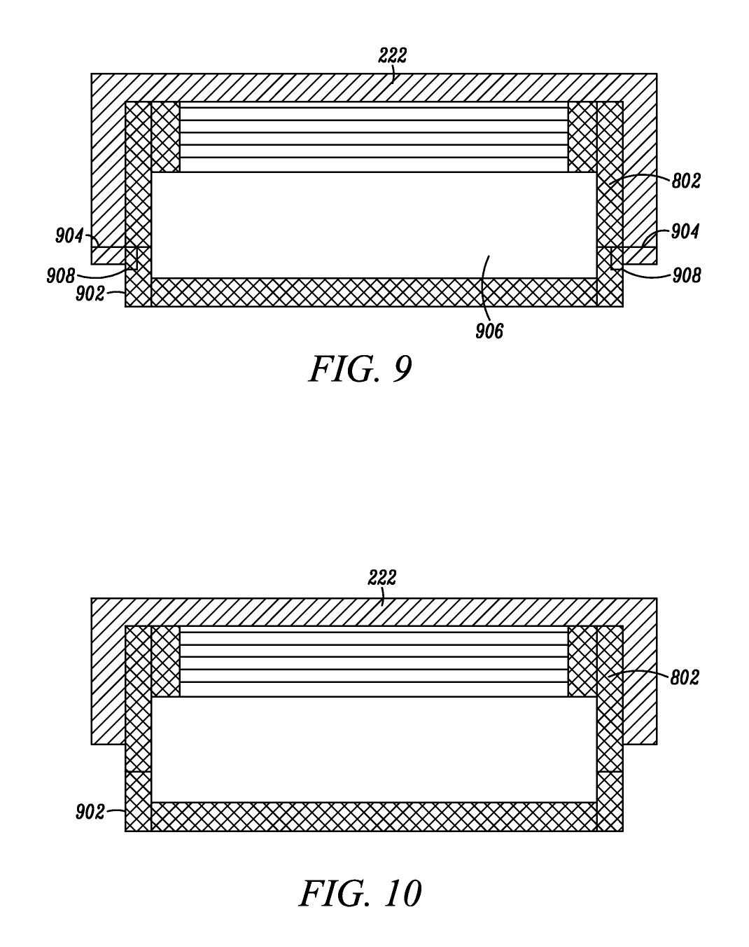

As FIG. 2 illustrates, the protective film 222 is affixed to the topside 218 of the lens 212 and seamlessly extends beyond the lens 212 and across the seam 228 that separates the lens 212 and housing, such that the film 222 is affixed to one or more sides of the housing 202. In this example, the protective film 222 extends to a bottom edge of the top housing plate 202, but in other examples the film 222 does not extend this far. Accordingly, in this embodiment, the protective film 222 is disposed such that a topside 226 of the housing 202 is covered with the film 222, and the film 222 is further affixed to sides 224 of the housing 202 such that the protective film 222 covers the entire top housing plate. However, in other embodiments, the protective film only extends along the topside 226 of the top housing plate 202 or partially down the sides 224 of the top housing plate 202. In still other examples, the protective film 222 extends below the top housing plate 202 to a bottom housing plate (not shown in FIG. 2 but described later by reference to FIG. 9 and FIG. 10).

Additionally, the lens 212 depicted in FIG. 2 is illustratively included within a display, for instance for a portable device. For example, the display includes the lens 212 bonded, e.g., using a suitable adhesive, to the display assembly or panel 214 at the bottomside 220 of the lens 212. The display assembly 214 is further connected to other electronics (not shown) internal to the portable device. Example displays include, but are not limited to, a liquid crystal display (LCD), an organic light-emitting diode (OLED) display, a plastic OLED display, and an e-ink type display. Moreover, in some embodiments, there is a gap 216 or space between the display assembly 214 and the housing 202. The gap 216 can be used to protect the display assembly from damage, for instance by preventing the housing 202 from contacting or rubbing against the display assembly 214.

Turning now to FIG. 3, which describes an embodiment of a general method 300 of seamlessly affixing a protective film to a lens and housing, such as the lens 212 and housing 202 illustrated in FIG. 2. The method 300 represents part of a process for manufacturing an electronic device such as the electronic device 100 of FIG. 1. Accordingly, the part of the device manufacturing process as relates to the present innovation and as depicted by the method 300 includes affixing 302 a protective film to a topside of the lens such that an empty space is formed between a perimeter of the lens and the protective film. For instance, as described above, in one example implementation, affixing the protective film to the topside of the lens includes affixing to the topside of the lens a protective film having at least one of a layer of diamond-like material, a polycarbonate layer, a poly(methyl methacrylate) layer, or a polyethylene terephthalate layer. The method 300 further includes, in general, inserting 304 housing material within the empty space such that the protective film is seamlessly affixed to the topside of the lens and to the housing material. In one embodiment, the housing material forms at least a portion of the housing, such as the top housing plate, of the electronic device 100.

Method 300 can be included within or applied to any suitable electronic device manufacturing process or portion thereof. In one particular embodiment, the protective film is seamlessly affixed to the topside of the lens and to the housing material using a molding tool during a glass insert molding process. The term glass insert molding process is meant to include any injection molding process that integrates a glass or other rigid lens with housing material, for instance, to manufacture a face cover for an electronic device, such as a portable electronic device.

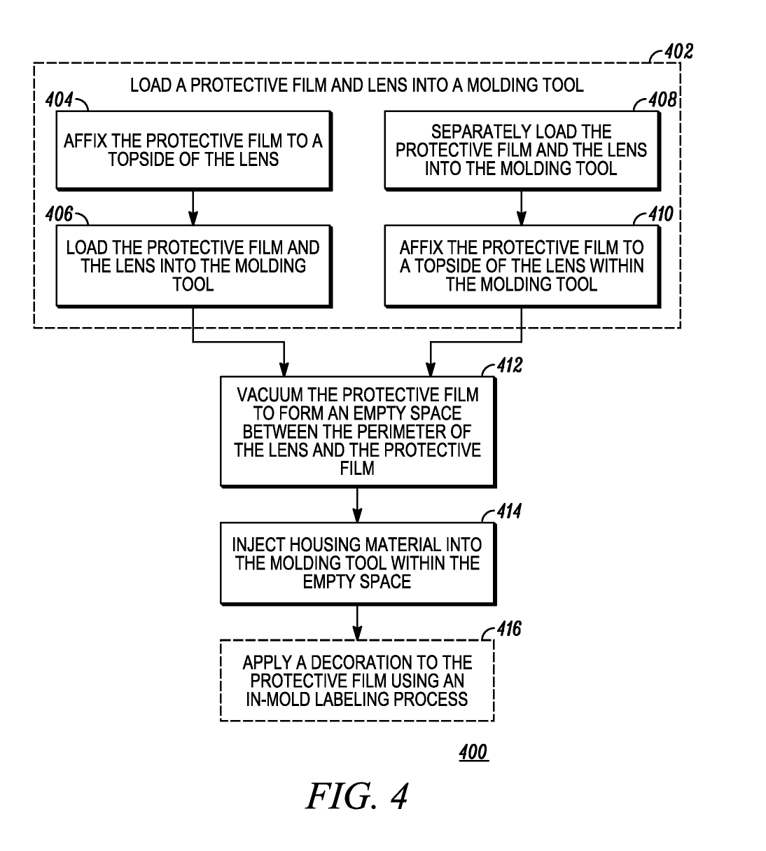

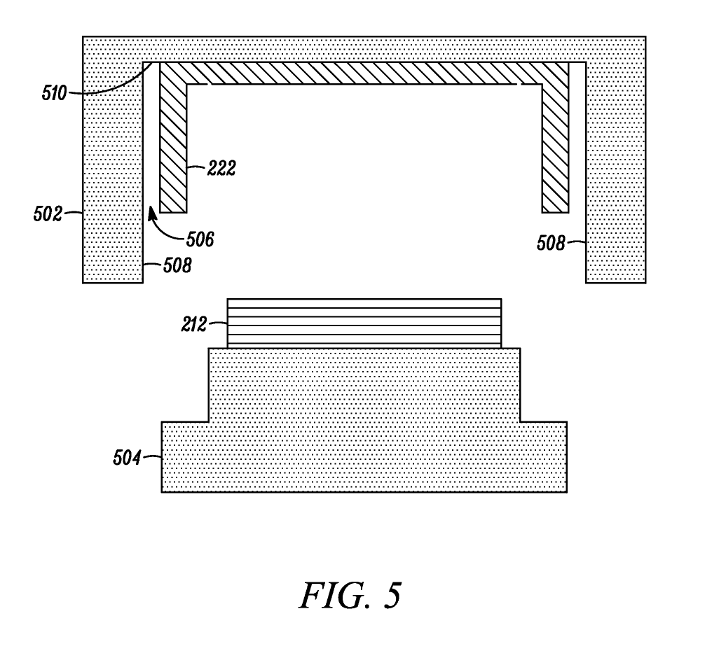

Such an embodiment is further described with respect to FIG. 4, which illustrates an example method 400 of seamlessly affixing the protective film to a lens and housing using a molding tool during a glass insert molding process. This embodiment is also described with respect to FIGS. 5-8, which each shows a molding tool having a cavity component 502 with sides 508 and 510 and a core component 504 and also shows the lens 212 and protective film 222 of FIG. 2. Particularly, FIGS. 5-8 illustrate schematic diagrams showing the molding tool 502, 504 at different stages of the performing of method 400 to affix the protective film 222 to the lens 212 and to housing material during the glass insert molding process. Accordingly, FIGS. 5-8 are selectively introduced while describing corresponding functional elements of the method 400.

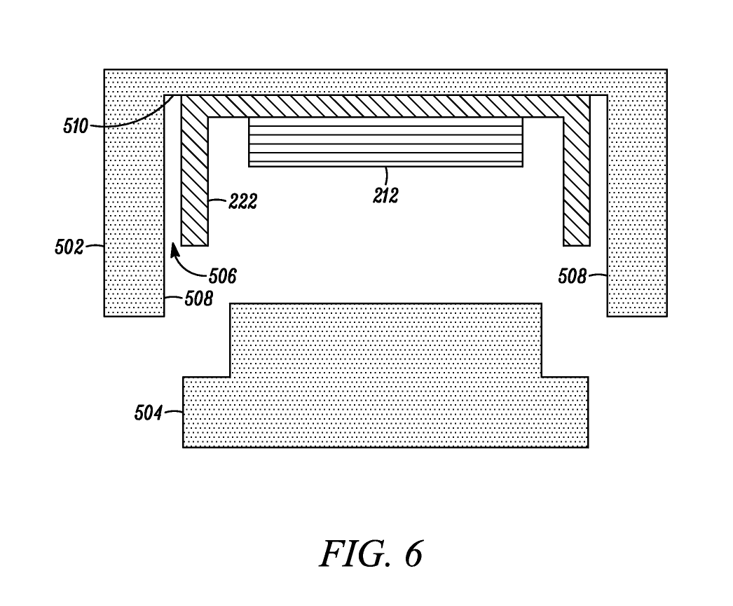

Turning now to the details of the illustrative glass insert molding process as shown with respect to the method 400, which starts with the protective film 222 and the lens 212 being loaded 402 into the molding tool 502, 504. This can be done manually or as an automated function. In a first embodiment, further illustrated by reference to FIG. 5, the protective film 222 and the lens 212 are separately loaded 408 into the molding tool 502, 504, and the protective film 222 is affixed 410 to the topside of the lens within the molding tool 502, 504. In a second embodiment, further illustrated by reference to FIG. 6, the protective film 222 is affixed 404 to the topside of the lens 212 before loading 406 the lens 212 and the protective film 222 into the molding tool 502, 504.

For example, for the first embodiment illustrated in FIG. 5, the lens 212 is loaded onto the core component 504 of the molding tool, and the protective film 222 is loaded within a cavity 506 of the cavity component 502 of the molding tool. Depending on the orientation of the molding tool, the lens 212 and protective film 222 can be, for instance, laid or sat on the respective molding tool components or vacuumed or otherwise suctioned or held (e.g., using a vacuum and compressed air, static electricity, etc.) onto the respective molding tool components to properly arrange the lens 212 and protective film 222 within the molding tool.

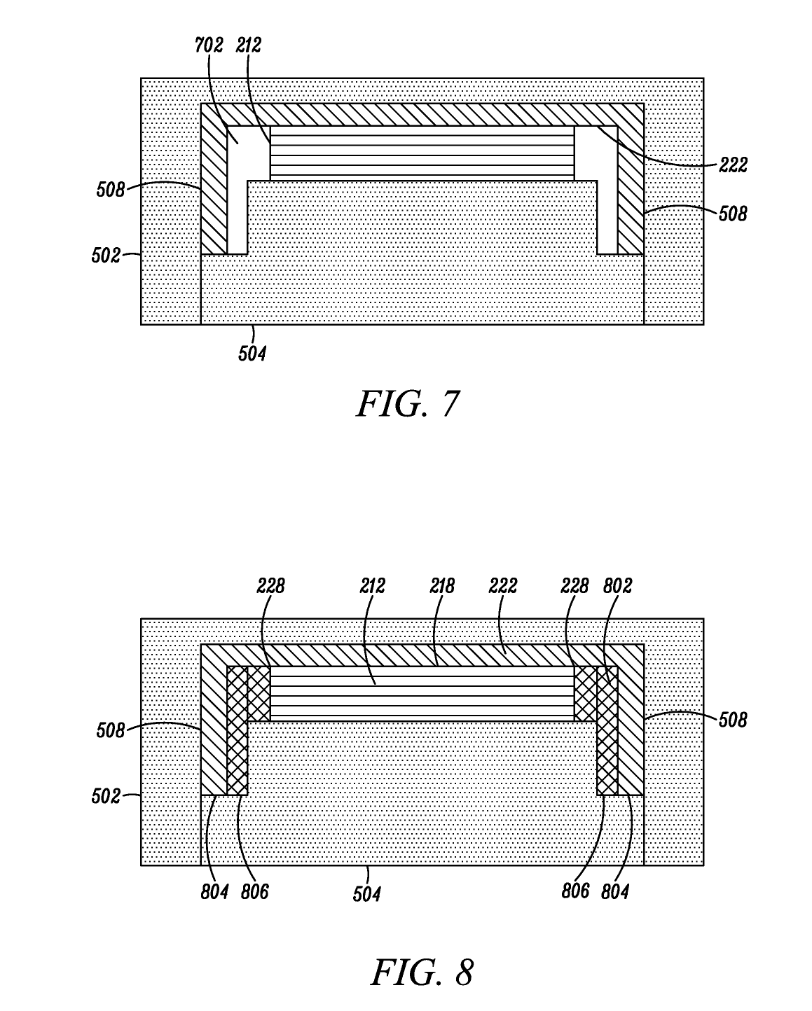

In a particular implementation of the first embodiment shown in FIG. 5, an adhesive is added to the lens 212 and/or the protective film 222. As shown in FIG. 7, bringing the two components 502, 504 of the molding tool together affixes 410 the protective film 222 to the lens 212 within the molding tool. Moreover, in both embodiments shown in FIGS. 5 and 6, the protective film 222 is vacuumed 412 to hold or seal it to sides the 508 and 510 of the cavity component 502. Vacuuming 412 the protective film 222 to the sides 508 and 510 of the cavity component 502 enables the forming of an empty space 702 between the perimeter of the lens 212 and the protective film 222, as further shown in FIG. 7. Housing material 802, which generates at least a portion of the housing 202, is then injected 414 into the empty space 702, such that the protective film 222 is seamlessly affixed to both the lens 212 and the housing material 802, as shown in FIG. 8.

More specifically, as illustrated in this example, inserting the housing material 802 within the empty space 702 creates the seam 228 between the lens 212 and the housing material 802 that makes up the at least a portion of the housing 202 and causes the protective film 222 to cover the seam 228 between the lens 212 and the housing material 802. Moreover, in the embodiment illustrated in FIG. 8, inserting the housing material 802 within the empty space 702 creates a top housing plate interchangeably indicated at 802. The top housing plate 802 is molded to the lens 212 and causes the protective film 222 to cover the topside 218 of the lens 212 and at least a portion of the top housing plate 802. In this particular example, the protective film 222 covers only the top housing plate 802. Moreover, an edge 804 of the protective film 222 lines up with an edge 806 of the top housing plate 802, such that the protective film 222 covers the entire top housing plate. However, in other embodiments, the edge 804 of the protective film 222 does not line up with the edge 806 of the top housing plate 802, as shown for instance in FIG. 9 and FIG. 10.

FIG. 9 illustrates some components of an assembled electronic device 900, namely the top housing plate 802, molded together with the lens 212 and with the protective 222 covering the lens 212 and the top housing plate 802, and a bottom housing plate 902 that abuts and is connected to the top housing plate 802. In one example arrangement, the bottom housing plate 902 is created using the same housing material used to create the top housing plate. In addition, although not shown, additional electronic components fill an internal area 906 of the assembled electronic device 900.

As shown in FIG. 9, the edge 804 of the protective film 222 extends beyond the edge 806 of the top housing plate 802. Accordingly, the protective film 222 covers all of the top housing plate 802 and at least a portion of the bottom housing plate 902. In one example implementation, the protective film is applied during or after assembling the top housing plate 802 to the bottom housing plate 902. Where a cut 904 is made in the protective film at a seam 908 to enable a user to separate the top 802 and bottom 902 housing plates after manufacturing, any perceptibility of the cut 904 by a user is much less than the above-mentioned perceptibility, in the prior art, of the seam between the lens and the top housing plate. In an alternative arrangement shown in FIG. 10, the edge 804 of the protective film 222 stops short of the edge 806 of the top housing plate 802, such that the protective film only covers a portion or some of the top housing plate.

In a further embodiment, a decoration can be applied 416 to the protective film 222 and/or the lens 212 using an in-mold labeling process, so that when the mobile device is completed, the mobile device includes one or more decorative features, such as those illustrated with respect to the mobile device 100 in FIG. 1. For example, the decorative features are applied as a label during an injection molding process in which the lens is formed together with the top housing plate and during which the protective film is applied in accordance with the present teachings. In a particular embodiment, the in-mold labeling process is combined with the glass insert molding process to transfer ink from a plastic label to the outermost layer of the protective film 222 to generate the decorative features. Alternatively, the decorative ink is transferred to the lens 212 before affixing the protective film 222 to the lens 212.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has,” “having,” “includes,” “including,” “contains,” “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a,” “has . . . a,” “includes . . . a,” or “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially,” “essentially,” “approximately,” “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically.

A device or structure that is “configured” in a certain way is configured in at least that way, but may also be configured in ways that are not listed. As used herein, the terms “configured to”, “configured with”, “arranged to”, “arranged with”, “capable of” and any like or similar terms mean that elements of the device or structure are at least physically arranged, connected, and or coupled to enable the device or structure to function as intended.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

We claim:

1. A method for seamlessly affixing a protective film, the method comprising:
affixing a protective film to a topside of a lens such that an empty space is formed between a perimeter of the lens and the protective film;
inserting housing material within the empty space such that the protective film is seamlessly affixed to the topside of the lens and the housing material.

2. The method claim 1, wherein the protective film is seamlessly affixed to the topside of the lens and the housing material using a molding tool during a glass insert molding process.

3. The method of claim 2, wherein the glass insert molding process comprises:
vacuuming the protective film to form the empty space between the perimeter of the lens and the protective film after the protective film and the lens are loaded into the molding tool;
injecting the housing material into the molding tool within the empty space.

4. The method of claim 2, wherein the protective film is affixed to the topside of the lens before loading the lens and the protective film into the molding tool.

5. The method of claim 2, wherein the protective film and the lens are separately loaded into the molding tool, and the protective film is affixed to the topside of the lens within the molding tool.

6. The method of claim 2 further comprising applying a decoration to the protective film using an in-mold labeling process.

7. The method of claim 1, wherein affixing the protective film to the topside of the lens comprises affixing to the topside of the lens a protective film having at least one of a layer of diamond-like material, a polycarbonate layer, a poly(methyl methacrylate) layer, or a polyethylene terephthalate layer.

8. The method of claim 1, wherein inserting the housing material within the empty space creates a seam between the lens and the housing material and causes the protective film to cover the seam between the lens and the housing material.

9. The method of claim 1, wherein inserting the housing material within the empty space creates a top housing plate molded to the lens and causes the protective film to cover the topside of the lens and at least a portion of the top housing plate.

10. The method of claim 9 further comprising:
creating a bottom housing plate using the housing material;
covering at least a portion of the bottom housing plate using the protective film.

11. An apparatus configured with a seamlessly affixed protective film, the apparatus comprising:
a lens having a topside, a bottomside, and a perimeter around the lens;
a housing surrounding at least a portion of the perimeter of the lens, wherein a seam separates the lens and the housing;
a protective film affixed during a manufacturing process to cover the topside of the lens and to extend across the seam to cover at least a portion of the housing.

12. The apparatus of claim 11, wherein the housing comprises a top housing plate and a bottom housing plate, and the protective film covers only the top housing plate.

13. The apparatus of claim 12, wherein the protective film is affixed during an injection molding manufacturing process that also molds the top housing plate to the lens.

14. The apparatus of claim 11, wherein the housing comprises a top housing plate and a bottom housing plate, and the protective film covers the top housing plate and at least a portion of the bottom housing plate.

15. The apparatus of claim 11, wherein the lens is at least one of a transparent glass lens or a transparent rigid plastic lens.

16. The apparatus of claim 11, wherein the protective film comprises polyethylene terephthalate.

17. The apparatus of claim 11, wherein the protective film comprises a polycarbonate layer in contact with the lens.

18. The apparatus of claim 17, wherein the protective film further comprises a poly(methyl methacrylate) layer disposed over the polycarbonate layer.

19. The apparatus of claim 11, wherein the protective film comprises a first poly(methyl methacrylate) layer in contact with the lens.

20. The apparatus of claim 19, wherein the protective film further comprises a polycarbonate layer disposed over the first poly(methyl methacrylate) layer and a second poly(methyl methacrylate) layer disposed over the polycarbonate layer.
